(19) United States
(12) Patent Application Publication
(10) Pub. No.: US 2010/0006895 A1
(43) Pub. Date: Jan. 14, 2010

(54) III-NITRIDE SEMICONDUCTOR DEVICE

(76) Inventors: Jianjun Cao, Torrance, CA (US); Robert Beach, Altadena, CA (US); Sadiki Jordan, Torrance, CA (US)

Correspondence Address: FARJAMI & FARJAMI LLP, 26522 LA ALAMEDA AVENUE, SUITE 360, MISSION VIEJO, CA, 92691, US

(21) Appl. No.: 12/351,967

(22) Filed: Jan. 12, 2009

Related U.S. Application Data
(60) Provisional application No. 61/020,174, filed on Jan. 10, 2008.

(51) Int. Cl. H01L 29/778; H01L 21/335

(52) U.S. Cl. 257/192; 438/285; 257/E29.246; 257/E21.403

(57) ABSTRACT

A III-nitride power switch that includes a III-nitride heterojunction, field dielectric bodies disposed over the heterojunction, and a gate electrode that does not overlap the top surface of the field dielectric bodies and is disposed over a well in the III-nitride heterojunction.

### RELATED APPLICATIONS

This application is based on and claims priority to U.S. Provisional Application Ser. No. 61/020,174, filed on Jan. 10, 2008, entitled GaN Device with Zero Gate Overlap for Reduced Gate Capacitance, to which a claim of priority is hereby made and the disclosure of which is incorporated by reference, and is related to U.S. patent application Ser. No. 12/009,045, entitled III-Nitride Power Device with Reduced Qgd, the entire disclosure of which is incorporated by reference.

### FIELD OF THE INVENTION

The present invention relates to III-nitride type power switching devices and more specifically relates to a III-nitride power switch with a reduced Qg and a process for the fabrication thereof.

### DEFINITION

III-nitride refers to a semiconductor alloy from the AlGaN system. Examples of III-nitride semiconductors are GaN, AlGaN, AlN, InAlGaN, InGaN, InN, or any combination thereof.

### BACKGROUND AND SUMMARY OF THE INVENTION

Referring to FIG. 1, a known III-nitride power semiconductor device includes III-nitride multilayer body 21 formed on a substrate 20. Substrate 20 is preferably formed of silicon, but may be formed of SiC, Sapphire or a III-nitride semiconductor such as GaN. Multilayer body 21 includes a III-nitride active heterojunction 21A. Active heterojunction 21A includes III-nitride barrier layer 21B (e.g. AlGaN) formed on a III-nitride channel layer 21C (e.g. GaN). As is well known, the thickness and composition of barrier layer 21B and channel layer 21C are selected so that a two-dimensional electron gas (2DEG) is formed in channel layer 21C close to the heterojunction of layer 21B and layer 21C. The current in the device is conducted through the 2DEG. Note that III-nitride multilayer 21 may include a III-nitride transition layer (e.g. formed with AlN), and a III-nitride buffer layer (e.g. GaN layer) disposed between substrate 20 and heterojunction 21A, when for example, substrate 20 is non-native (i.e. is not from the III-nitride semiconductor system) to the III-nitride system. For example, when silicon is used as a substrate material.

A device as described above further includes a first power electrode 30 (e.g. source electrode) coupled ohmically to heterojunction 21B and second power electrode 30′ (e.g. drain electrode) coupled ohmically to heterojunction 21A whereby current may be conducted between electrode 30, 30′ through the 2DEG. A gate dielectric body 27 is disposed over heterojunction 21A through which gate conductive body 35 can be capacitively coupled to the 2DEG in order to interrupt (depletion mode) or restore (enhancement mode) the same depending on the type of device.

The device further includes field dielectric bodies 25. Each field dielectric is disposed between a power electrode 30, 30′ and gate conductive body 35. As illustrated field dielectric body 25 is thicker than gate dielectric 27. Gate conductive body 35 extends over a field dielectric body 25. Note that each electrode 30, 30′ also rises along adjacently disposed field dielectric bodies 25 and overlaps a portion of the top surface thereof.

In the device shown by FIG. 1, overlap of the gate metal (a) over dielectric 25 contributes to gate to drain charge (Qgd). The overlap (b) of the ohmic electrodes 30 over dielectric 25 increases pitch size.

In a III-nitride device according to the present invention, either the overlap of gate metal or the overlap of ohmic metal over the field dielectric bodies, or both, are eliminated through, for example, a chemical mechanical polishing (CMP) step. As a result, Qg (total gate charge) of the device may be improved by reducing Qgd and Qgs, and also the cell pitch of the device may be improved.

In addition, in a device according to the present invention, a depression (a recess that does not extend all the way through) may be formed in the barrier layer directly under the gate to reduce electric field and allow lighter doping in the barrier layer in order to suppress the “hot electron” effect.

Other features and advantages of the present invention will become apparent from the following description of the invention which refers to the accompanying drawings.

### BRIEF DESCRIPTION OF THE DRAWINGS

FIG. 1 illustrates a cross-section of a III-nitride device according to the prior art.

FIG. 2 illustrates a first preferred embodiment of the present invention in which the ohmic contacts and gate contact terminate in the plane of the top of the field dielectric layer.

FIG. 3 shows a second embodiment of a device according to the present invention.

FIG. 4 shows a third embodiment of the invention.

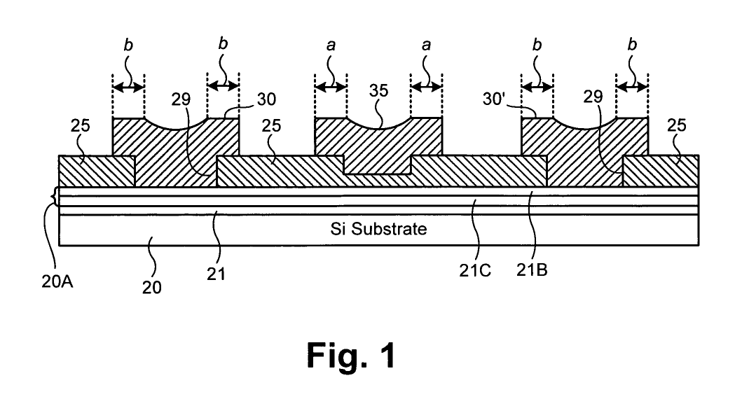

### BRIEF DESCRIPTION OF THE PREFERRED EMBODIMENTS

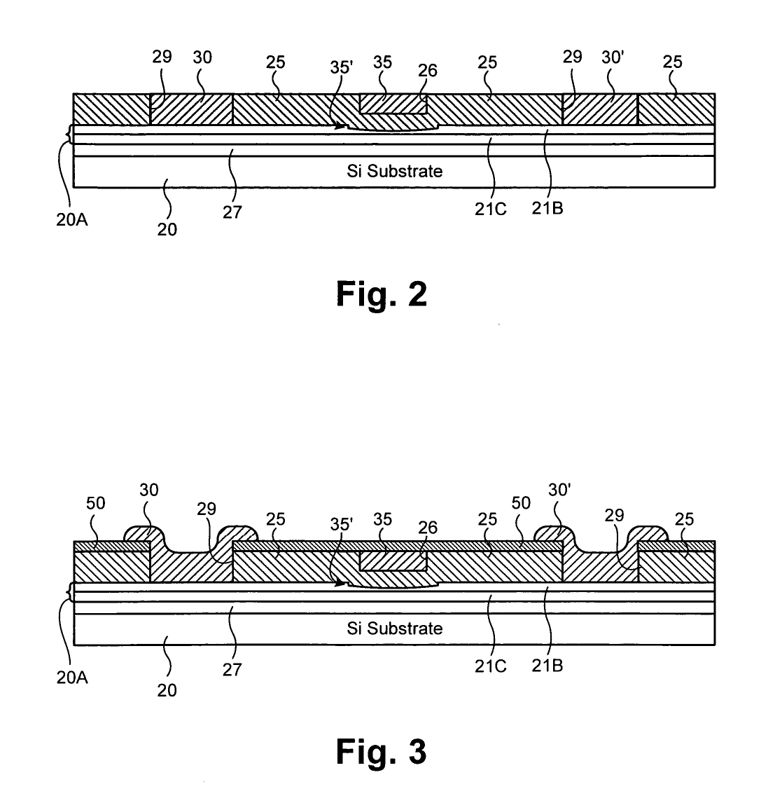

Referring to FIG. 2, in which like numerals identify like features as discussed above, a III-nitride power switch according to the first embodiment of the present invention includes gate conductive body 35 that does not overlap the top surface of adjacently disposed field dielectric bodies 25. Preferably, gate conductive body 35 includes a top surface that is coplanar with top surfaces of adjacently disposed field dielectric bodies 25. As a result, a device according to the first embodiment may exhibit a reduced Qg value.

Furthermore, in a device according to the first embodiment, power electrodes 30, 30′ do not overlap the top surface of adjacently disposed field dielectric bodies 25. As a result, the cell pitch of a device according to the first embodiment may be reduced, which in turn allows for reduction of R_{DSON} of the device by allowing a greater number of active cells per unit area.

According to another aspect of the present invention, a depression 35′ in the form of a shallow well is etched into the surface of barrier layer 21B in alignment with and directly under gate 35. Well 35′ reduces the field at the bottom corners of gate 35 and permits lighter doping of barrier layer 21B which tends to suppress the “hot-electron” effect. Note that well 35′ does not extend through barrier layer 21B. That is, well 35′ extends partially into barrier layer 21B.

Referring now to FIG. 3, in which like numerals identify like features, a III-nitride switch according to the second embodiment of the present invention includes gate conductive body 35 that does not overlap the top surface of adjacently disposed field electric bodies 25 (and preferably includes a top surface coplanar with top surfaces of field dielectric bodies 25), while power electrodes 30, 30′ overlap the top surface of adjacently disposed field dielectric bodies. Note that in a device according to the second embodiment, an etch stop layer 50 can be disposed above gate conductive body 35 after the planarization thereof to protect dielectric bodies 25 and gate conductive body 35 during the fabrication of power contacts 30, 30′.

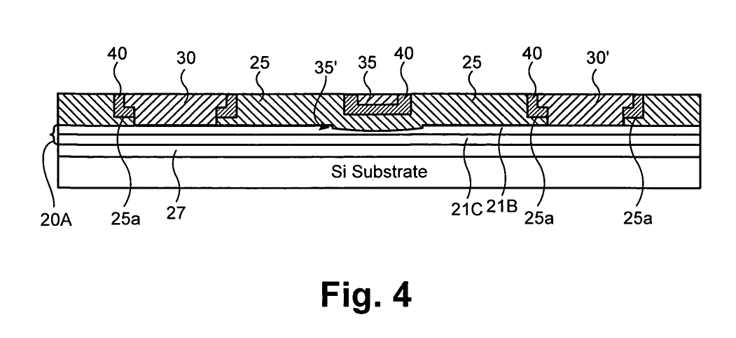

Referring to FIG. 4, in which like numerals identify like features, a device according to the third embodiment also includes gate conductive bodies 35 that do not overlap the top surfaces of adjacently disposed field dielectric bodies (and preferably include top surfaces coplanar with the top surfaces of adjacently disposed field dielectric bodies 25), and at least one power contact 30 that does not overlap the top surface of adjacently disposed field dielectric bodies 25. Note that a device according to the third embodiment includes barrier bodies 40 disposed under gate conductive bodies 35, and at least on opposing sides of power contact 30. The application of barrier bodies 40 is disclosed in U.S. patent application Ser. No. 11/702,727, entitled III-nitride Semiconductor Device, filed Feb. 6, 2007, assigned to the assignee of the present application, the entire content of which is incorporated by this reference. Note that a device according to the third embodiment includes dielectric lips 25 under barrier bodies 40 that are adjacent to power contact 30. According to the present invention, barrier bodies 40 also do not overlap the top surface of adjacently disposed field dielectric bodies 25, and are preferably coplanar with adjacently disposed field dielectric bodies 25.

To fabricate a device according to the present invention, an epitaxially deposited III-nitride multilayer structure 21 is built atop substrate 20, using any desired method. Structure 21 includes at least one III-nitride heterojunction having a two-dimensional electron gas (2DEG) to serve as a conductive channel. For example, structure 21 includes a heterojunction between a GaN layer 21C and an AlGaN layer 21B that produces a 2DEG layer (not shown) which permits conduction between a source and a drain contact, under the control of a gate structure. Note that substrate 20 may be preferably a silicon wafer, but may also be a SiC wafer, Sapphire wafer, or a III-nitride wafer such as a GaN wafer, without deviating from the scope and the spirit of the invention. According to an aspect of the present invention, a well 35′ is formed in the AlGaN layer 21B through an etching step.

Next, a field dielectric layer 25 is formed atop layer 21 and an active mask step is employed to etch windows 26 in the field dielectric layer 25. A thin gate dielectric layer 27 is then formed at the bottom of windows 26 over well 35′.

Thereafter, conductive gate metal are deposited inside openings 26 and patterned to obtain gate conductive bodies 35 inside windows 26 over gate dielectric bodies 27. Preferably, in the same step, windows 29 are opened in field dielectric bodies 25 for the reception of contact metal. Next, contact metal is deposited inside windows 29, and thereafter, in a chemical mechanical polishing (CMP) step, the excess metal is removed until at least the top surface of field dielectric bodies is reached. As a result, a III-nitride device is obtained according to the first embodiment that includes gate conductive bodies 35 and power contacts 30, 30′ that do not overlap the top surface of adjacently disposed field dielectric bodies 25.

Note that a rapid thermal appeal (RTA) can be applied after the CMP step or before the CMP step. A typical RTA is carried out at 800.degree. C. to 900.degree. C. for 30 seconds to 120 seconds. Thereafter, other features such as gate, source, and drain routing can be fabricated according to any desired method.

To fabricate a device according to the third embodiment, a device can be fabricated as set forth in U.S. application Ser. No. 11/702,727 with the added step necessary to form well 35′, and then subjected to a CMP step according to the present invention. Thus, the fabrication of a device according to the third embodiment may include the deposition or otherwise the formation of a barrier body 46 after the gate dielectric deposition.

To fabricate a device according to the second embodiment, after the deposition of a gate metal, a CMP step is applied to obtain a gate conductive body 35 that does not overlap adjacently disposed field dielectric bodies. Thus, the CMP stops at least at the top surface of field dielectric bodies 25. Thereafter, a thin layer of oxide or nitride is deposited atop field dielectric bodies 25 and conductive gate bodies 35 to serve as an etch stop layer 50. Next, field dielectric bodies 25 are patterned to include windows 29 for the reception of contact metal. Next, contact metal is deposited and patterned to obtain power contacts 30, 30′ according to the second embodiment.

To fabricate a device according to the second embodiment, after the deposition of a gate metal, a CMP step is applied to obtain a gate conductive body 35 that does not overlap adjacently disposed field dielectric bodies. Thus, the CMP stops at least at the top surface of field dielectric bodies 25. Thereafter, a thin layer of oxide or nitride is deposited atop field dielectric bodies 25 and conductive gate bodies 35 to serve as an etch stop layer 50. Next, field dielectric bodies 25 are patterned to include windows 29 for the reception of contact metal. Next, contact metal is deposited and patterned to obtain power contacts 30, 30′ according to the second embodiment.

To fabricate a device according to the fourth embodiment, field dielectric layer 25 is first patterned to include windows 29 for the reception of power contacts 30, 30′, contact metal is deposited, and according to the present invention a CMP step is applied to remove the contact metal. The CMP preferably stops at the top surface of field dielectric bodies 25, whereby power contacts 30, 30′ are obtained that do not overlap adjacently disposed field dielectric bodies. Next, an etch stop layer 28 (e.g. an oxide or a nitride layer) is applied atop field dielectric bodies 25 and the planarized power contacts 30, 30′. Thereafter, windows 26 are opened in the field dielectric layer, gate dielectric 27 is deposited at the bottom of windows 26, and gate metal is deposited inside windows 26 and patterned to obtain gate conductive bodies 35 as illustrated by FIG. 5. Note that etch stop layer 28 prevents damage to field dielectric bodies 25 and power contacts 30, 30′ during the patterning of gate metal to obtain gate conductive bodies 35.

Field dielectric 25 can be a silicon nitride, or silicon oxynitride, or a metal oxide such as Al₂O₃, HfO₂, having a thickness of 500 Å to 5000 Å. Gate dielectric 27 can be silicon nitride or a metal oxide such as SiO₂, Al₂O₃, HfO₂, TiO₂ having a thickness of 20 Å to 500 Å.

The contact metal 30, 30′ include Ti and Al and capping layers such a Ni/Au, Mo/Au, Ti/TiW, Ti/TiN.

It should be noted that each III-nitride power semiconductor device according to the present invention includes a III-nitride multilayer body 21 formed on a substrate 20. Substrate 20 is preferably formed of silicon, but may be formed of SiC, Sapphire or a III-nitride semiconductor such as GaN. Multilayer body 21 includes a III-nitride active heterojunction 21A. Active heterojunction 21A includes III-nitride barrier layer 21B (e.g. AlGaN) formed on a III-nitride channel layer 21C (e.g. GaN). The thickness and composition of barrier layer 21B and channel layer 21C are selected so that a two-dimensional electron gas (2DEG) is formed in channel layer 21C close to the heterojunction of layer 21B and layer 21C. The current in the device is conducted through the 2DEG. Note that III-nitride multilayer 21 may include a III-nitride transition layer (e.g. formed with AlN), and a III-nitride buffer layer (e.g. GaN layer) disposed between substrate 20 and heterojunction 21A, when for example, substrate 20 is non-native (i.e. is not from the III-nitride semiconductor system) to the III-nitride system. For example, when silicon is used as a substrate material.

First power electrode 30 (e.g. source electrode) is preferably coupled ohmically to heterojunction 21B and second power electrode 30′ (e.g. drain electrode) is preferably coupled ohmically to heterojunction 21A whereby current may be conducted between electrode 30, 30′ through the 2DEG. Gate conductive body 35 can be capacitively coupled to the 2DEG through gate dielectric body 27 in order to interrupt (depletion mode) or restore (enhancement mode) the same depending on the type of device.

Each field dielectric body 25 is disposed between a power electrode 30, 30′ and gate conductive body 35. As illustrated field dielectric body 25 is thicker than gate dielectric 27. Note that each power electrode 30, 30′ also rises along adjacently disposed field dielectric bodies 25.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A III-nitride power semiconductor switch, comprising: a III-nitride heterojunction that includes a III-nitride channel layer and a III-nitride barrier layer formed over said III-nitride channel layer; spaced field dielectric bodies over said III-nitride heterojunction; a well formed in said III-nitride barrier layer; and a gate electrode disposed in the space between said field dielectric bodies and directly over said well in said III-nitride barrier layer, wherein said conductive body does not overlap a top surface of said field dielectric bodies.

2. The switch of claim 1, wherein said gate electrode includes a top surface that is coplanar with the top surfaces of said field dielectric bodies.

3. The switch of claim 1, further comprising a gate dielectric disposed between said gate electrode and said III-nitride heterojunction.

4. A III-nitride power semiconductor switch, comprising: a III-nitride heterojunction that includes two III-nitride bodies having different band gaps from one another; field dielectric bodies over said III-nitride heterojunction, said dielectric bodies being spaced from one another by a first space and a second space; a recess formed in a first one of the two III-nitride bodies; a first power electrode disposed in said first space; and a gate electrode disposed in said second space directly over said recess, wherein said gate electrode does not overlap a top surface of said field dielectric bodies.

5. The switch of claim 4, further comprising a gate dielectric between said gate electrode and said III-nitride heterojunction.

6. The switch of claim 4, wherein said first power electrode does not overlap a top surface of said field dielectric bodies.

7. The switch of claim 4, wherein said first power electrode and said gate electrode have top surfaces coplanar with top surfaces of said field dielectric bodies.

8. The switch of claim 4, wherein said gate electrode includes a top surface that is coplanar with a top surface of said field dielectric bodies.

9. A method for fabricating a III-nitride semiconductor switch, comprising: forming a III-nitride heterojunction; forming a recess in said III-nitride heterojunction; forming a field dielectric layer over said III-nitride heterojunction; opening a window inside said field dielectric layer directly over said recess; depositing a conductive body inside said window and over top surfaces of said field dielectric layer; and removing portions of said conductive body from atop said field dielectric layer including any portion of said conductive body that overlaps a top surface of said field dielectric layer.

10. The method of claim 9, wherein said portions of said conductive body is removed using CMP.

11. The method of claim 9, further comprising covering said top surfaces of said dielectric body and said conductive body inside said window with an etch stop layer; patterning said dielectric body to form another window therein; and depositing another conductive body inside said another window.

12. The method of claim 9, further comprising opening another window in said field dielectric layer after said depositing step; and depositing another conductive body in said another window prior to said removing step.

13. The method of claim 12, wherein said removing step also removes any portion of said another conductive body that overlaps said field dielectric layer.

14. The method of claim 13, wherein said removing comprises a CMP step.
